(19) United States
(12) Patent Application Publication
(10) Pub. No.: US 2012/0275617 A1
(43) Pub. Date: Nov. 1, 2012

(54) ORNAMENTAL DEVICE

(75) Inventors: Dorte Servé, Copenhagen V (DK); Henrik Ehlert, Græsted (DK)

(73) Assignee: SERVE PRODUKTION, Copenhagen V (DK)

(21) Appl. No.: 13/458,648

(22) Filed: Apr. 27, 2012

(30) Foreign Application Priority Data
Apr. 27, 2011 (DK) PA 2011 70201
May 2, 2011 (EP) 11164463.9

(51) Int. Cl. H04B 3/00; H03G 3/00

(52) U.S. Cl. 381/77

(57) ABSTRACT

The present invention relates to an ornamental device comprising a housing including an opening for emitting sound, a sound emitting device mounted in the housing, a memory device in the housing for storing sound to be emitted, a processor configured to access the memory device and configured to operate the sound emitting device so as to emit desired sounds, and a transceiver for transmitting the sound stored in the memory device to a neighboring ornamental device.

### CROSS-REFERENCE TO RELATED APPLICATIONS

This application claims the benefit of priority to Danish Application Number PA 2011 70201, filed Apr. 27, 2011, and European Patent Application Number 11164463.9, filed May 2, 2011, all of which are hereby expressly incorporated by reference in their entireties.

### FIELD OF THE INVENTION

The present invention relates to ornaments with music playing capabilities.

### BACKGROUND OF THE INVENTION

When decorating for a specific holiday, e.g. Christmas, Easter, Valentine's Day or the like, a lot of people wish to have a musical supplement to the visual decorations. The sound from such an ornament is not very impressive. Hence, an improved ornament would be advantageous, and a superior sound emitting ornament is advantageous.

It is desirable to provide a device achieving the above mentioned improvements. It is a further desirable to provide an alternative to similar devices that are currently available.

Other devices are described in publications such as WO 2004/036540, U.S. Pat. No. 4,652,980 and US 2008/0160224.

### SUMMARY OF THE INVENTION

Thus, the above described features are intended to be obtained in a first aspect of the invention by providing:

The invention is particularly, but not exclusively, advantageous for obtaining an ornamental device comprising a housing including an opening for emitting sound. The ornamental device may comprise a sound emitting device mounted in the housing. The ornamental device may comprise a memory device in the housing for storing sound to be emitted. The ornamental device may comprise a processor configured to access the memory device and configured to operate the sound emitting device so as to emit desired sounds. The ornamental device may comprise a transceiver for transmitting the sound stored in the memory device to a neighboring ornamental device.

Such an ornamental device is capable of providing sound at e.g. a Christmas tree, a Christmas decoration, a Valentine's Day heart or the like. The housing of the ornamental device may be shaped as an orb, sphere, ball, heart, train, sledge, Santa Claus, reindeer, Christmas bell, droplet or any other suitable decoration shape.

Advantageously the housing may be transparent, or at least allow low-loss transmission, to the radio frequency or frequency band of the transceiver, or comprise a radio wave transparent window for allowing communication from the transceiver. Alternatively at least part of the antenna may be external to the housing.

The transceiver may be used for establishing communication to another ornamental device. Here the term neighboring may be construed as any ornamental device within communication range of the transceiver. The effective range of the transceiver may be in the range 1 to 60 meters. Advantageously the transceiver may be ZigBee or Bluetooth based.

The ornamental device preferably includes a power source. The power source may be a rechargeable battery. A socket for providing power for recharging the rechargeable battery may be provided. Further the ornamental device may be placed in a docking station for charging one or more rechargeable batteries in the ornamental device or a power cord may be connected to the batteries for charging, e.g. via transformer external to the ornamental device. The power source may be an exchangeable battery where one battery is exchanged with another battery when the first is depleted.

The sound emitting device is advantageously a fulltone speaker. Advantageously the sound emitting device has a relatively flat frequency response.

Advantageously the sounds to be played by the ornamental device is recordings of songs, i.e. vocal and music, or music only,

Advantageously the memory device is a flash device. Other suitable memory devices may be employed. The memory device may allow that new pieces of sound are recorded in the memory device, e.g. new songs. The memory device may allow that a sound is temporarily stored before it is emitted.

In a setting where e.g. two ornamental devices are present and each of the two devices have a unique song recorded in their respective memory devices, e.g. one have “White Christmas” and the other have “Merry Christmas to You”, it is especially advantageous that the ornamental devices according to the present invention may unite and play the same song on both, or all if more devices are present, thereby establishing a larger choir of devices all emitting or playing the same song.

To distribute the sound, i.e. song or musical piece, a ornamental device may establish communication with other ornamental devices in the area and distribute the sound at that time. Alternatively the sound may be distributed when an ornamental device is operated to play the sound, this requires a larger bandwidth depending on the compression level and data rate of the sound.

Advantageously the transceiver is configured to receive sound information from a neighboring ornamental device. As mentioned in the present context neighboring ornamental device means one or more ornamental devices within communication range of the ornamental device. The ornamental device may establish a network with the other neighboring ornamental devices so as to monitor when one of the other devices are activated. Advantageously an ornamental device may act as a master device activating the other devices. The choice of master device is advantageously ad hoc and the master device determines which sound to play. E.g. if one ornamental device holds “White Christmas” then, when activated, all neighboring ornamental device will play “White Christmas”.

Advantageously the ornamental device may comprise a proximity sensor for establishing touch control of the ornamental device. The proximity sensor may be configured to detect touch or when a hand or finger is near. The proximity sensor may be coupled to the processor. The processor may then be configured to set the volume level of the sound to be played. Also, the signal from the proximity sensor may be used to start and stop the playing of the sound.

Advantageously the volume level may be controlled via the proximity sensor, e.g. by holding one or more fingers or the entire hand on the ornamental device for a period of time, the volume level shifts as a sine-like function, from a lowest level to a highest level and back again. The function for the change of volume level may be smooth or stepwise.

Advantageously the proximity sensor is a capacitive device. The proximity sensor may be implemented by a capacitive sensor configured to register presence of a hand and/or finger from a range of 30 cm from the surface of the ornamental device to actual touch of the surface.

Advantageously the ornamental device may comprise a microphone, wherein the processor is configured to adapt the volume of emitted sound via the sound emitting device based on information from the microphone.

Advantageously the processor is configured to detect back-ground sounds and perform the adaptation the volume of emitted sound via the sound emitting device based on the level of back-ground sound.

Advantageously the ornamental device may further comprise a lighting device. The lighting device may be configured to provide light of a number of different colors and/or intensities. The lighting device may comprise one or several independent light sources, e.g. LED light sources. Advantageously the housing may be transparent or translucent, allowing light to be emitted from inside the ornamental device. Advantageously the lighting source, or parts of it, may be located on or at the surface of the housing of the ornamental device.

A third aspect relates to a method of controlling an ornamental device comprising a housing including an opening for emitting sound, a sound emitting device mounted in the housing, a memory device in the housing for storing sound to be emitted, a processor arranged in the housing, the processor connected to the memory device and the sound emitting device, the processor comprising a software program for controlling playback of desired sounds stored in the memory, and a transceiver for transmitting the sound stored in the memory device to a neighboring ornamental device, the method comprising: operating the processor to cause stored sound from the memory to be emitted via the sound emitting device.

The method may advantageously be embodied in a software product to be executed e.g. on a processor. Such as software product may be included in an ornamental device according to any of the above aspects.

These and other aspects of the invention will be apparent from and elucidated with reference to the embodiments described hereinafter.

### BRIEF DESCRIPTION OF THE DRAWINGS

The ornamental device according to the invention will now be described in more detail with regard to the accompanying figures. The figures show one way of implementing the present invention and is not to be construed as being limiting to other possible embodiments falling within the scope of the attached claim set.

FIG. 1 is a schematic illustration of one embodiment of an ornamental device according to the present invention,

FIG. 2 is a schematic illustration of an insert device for placement in an ornamental device, and

FIG. 3 is a schematic illustration of some components of an ornamental device according to the present invention,

FIG. 4 is a schematic illustration of an insert device,

FIG. 4B is a schematic illustration

FIG. 5 is a schematic illustration of a part of an ornamental device,

FIG. 6 of a set of a housing and a closure device, and

FIG. 7 is a schematic illustration of a sectional or cut-through view of an ornamental device with a set of batteries.

FIG. 8 is a set of schematic illustrations of steps of operating an ornamental device.

FIG. 9 is a set of schematic illustrations of steps of operating the sound level of an ornamental device.

### DETAILED DESCRIPTION OF PREFERRED EMBODIMENTS

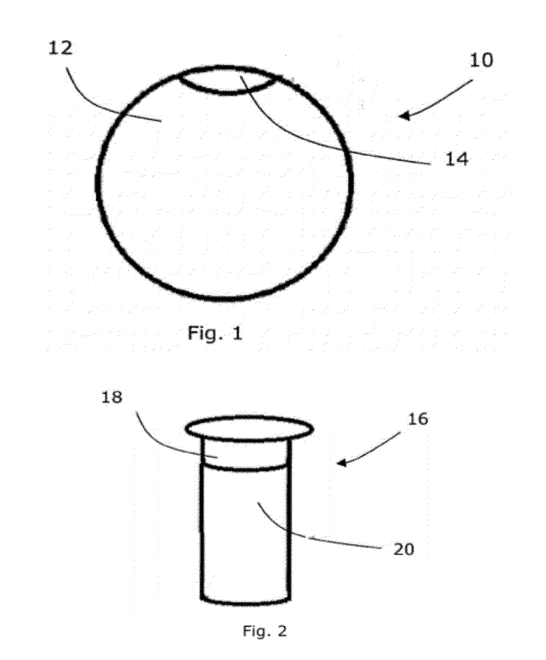

FIG. 1 is a schematic illustration of one embodiment of an ornamental device 10 according to the present invention. The ornamental device 10 comprises a housing 12 including an opening 14 for emitting sound. Inside the housing is mounted a sound emitting device, not visible in FIG. 1. Further, a memory device is located in the housing 12 for storing sound to be emitted. A processor that is configured to access the memory device and configured to operate the sound emitting device so as to emit desired sounds, e.g. Christmas songs is also mounted in the housing 12. Further, a transceiver for transmitting the sound stored in the memory device to a neighboring ornamental device.

In an embodiment the ornamental device 10 has a diameter of approximately 80 mm. The housing 12 will include an opening having one or more apertures for facilitating emission of sound from the sound emitting device in the housing. One aperture may also provide access for a charge lead so as to charge a rechargeable battery in the ornamental device 10. Further, a data connection may be established, e.g. via the charge lead which could be a USB-type connector, e.g. a micro-USB connector.

In order for the transceiver to function properly and without having high energy consumption, the housing should be made from a material that allows radio waves to pass through without too great a loss. Such material may e.g. be glass, porcelain, vinyl or other suitable materials. In the housing a window of a material different from the rest of the housing may be provided so as to establish a point of transmission. The housing may be coated with a metallic layer for aesthetic purposes, e.g. for establishing a shiny surface. Other ornamental features may be provided at the surface, e.g. illustrations of suitable holiday related objects. Further writing may be provided to the surface, e.g. for identification of a specific song that a particular ornamental device is capable of outputting.

The ornamental device 10 should include a mount for fastening a strap or the like so that the ornamental device 10 could be placed on a Christmas tree or the like.

FIG. 2 is a schematic illustration of an insert device 16 for placement in an ornamental device 10. The insert device 16 comprises a loud speaker part 18. The insert device 16 comprises a battery and electronics part 20. The elements mentioned in relation to FIG. 1 may be housed in the insert element 16. This allow the housing 12 to act as a resonant element for providing good quality sound from the ornamental device 10.

The insert device 16 may be provided separate from the housing 12. This allow production of the insert device 16 at one location and the housing 12 at a different location. The insert device 16 may be inserted into a range of devices having different shapes, the embodiment in FIG. 1 is spherical, but other embodiments are imaginable, e.g. hearts, cones or the like. The insert device 16 may include all electronic parts for the device.

A base station may be provided. The base station serves several purposes, first as a gateway between the ornamental devices and a WiFi-connection. Further the base station may comprise a bass-unit, e.g. a subwoofer or the like, so as to improve the quality of the sound in the room where the ornamental devices are placed. The base station is not required for the ornamental devices to function, but thought as a supplement. It will also provide possibility of higher sound volumes. If such a base station is present, the ornamental devices may filter out frequencies below a certain level, e.g. 500 Hz, as lower frequency sounds are better reproduced in larger cavities.

In an embodiment the sound emitting device is a 1″ loudspeaker unit. As the size of the loudspeaker limits the quality of the sound, the base station mentioned above may help heighted the sound experience. The base station may wirelessly communicate with the ornamental devices.

The base station may comprise wireless network communication capabilities allow communication over WLAN, e.g. IEEE 802.11n or the like. This will also allow communication with other wirelessly connectable devices, such as computers, PDA's, mobile telephones and the like. Such communication allows transfer of sound information, e.g. songs and/or music, to the ornamental devices. Also upgrade of firmware in the ornamental devices is possible.

Wireless communication may allow control of the ornamental devices via mobile phone applications, e.g. iPhone apps or Android apps.

In an embodiment two base stations may communicate over a data network, such as the internet. This could allow the same piece of music to be played at two different locations at the same time, allowing people being separated by large distances to have a virtual holiday experience. Further real-time distribution of audio messages is possible.

In an area with only one ornamental device present a proximity sensor may be used for controlling the ornamental device, e.g. as an on/off button. The proximity sensor may also be used as a volume control, e.g. by touching the ornamental device continuously the volume is altered. This could be embodied as a sine-like function raising and lowering the volume level over time. The function could be stepped or smooth.

The surface of the ornamental device could be provided with a text indication of which song the ornamental device is able to play. Advantageously when one ornamental device is present, it is able to play only one song.

In an area where multiple ornamental devices are present, and each of them comprises a specific song, the accumulated repertoire will increase by the number of ornamental devices. The ornamental devices will wirelessly exchange songs so that all ornamental devices comprise a digital copy of the songs. This lowers the bandwidth needed when several ornamental devices are to play the same song at one time. Alternatively each song is streamed to the individual ornamental devices when played. Preferably the ornamental devices establish a network where when one ornamental device is activated all ornamental devices play the same song. If an ornamental device is removed from the network, even if a digital copy of its song is present on the other ornamental devices this song is not playable until the ornamental device, or a similar ornamental device having the same song, is returned to the network.

The ornamental device may further comprise a microphone, wherein the processor is configured to adapt the volume of emitted sound via the sound emitting device based on information from the microphone. This allows adaptive volume control. If the microphone detects a high back-ground noise level, the processor may adapt sound level accordingly.

Further the microphone may be used for detecting singing in the surroundings so that the processor may adapt the level of the emitted sounds accordingly, e.g. so as not to drown the voices of the singers. Further, the sound in the memory may comprise two tracks where one track is music without song and one track is song alone. When song is detected in the surroundings the song is removed or decrease from the emitted sounds, and the song may be increased if people stop singing.

The ornamental device may have multiple tracks for the same song, one with music and the remaining tracks could be vocal in different keys—such that the network of devices would output multitrack music where each device outputs a unique track.

The ornamental device may further comprise a lighting device. The lighting device is configured to provide light of a number of different colors and/or intensities. The lighting device may include one or more individual light sources. The light source may be LED lights. This could e.g. be a red, green and blue LED. The lighting device may be operated by the processor. The lighting device may be varied in light color and/or intensity. The lighting device may be varied in light color and/or intensity so as to establish a specific pattern, e.g. based on the rhythm of the song. Data relating to control of the lighting device may be stored in the memory device.

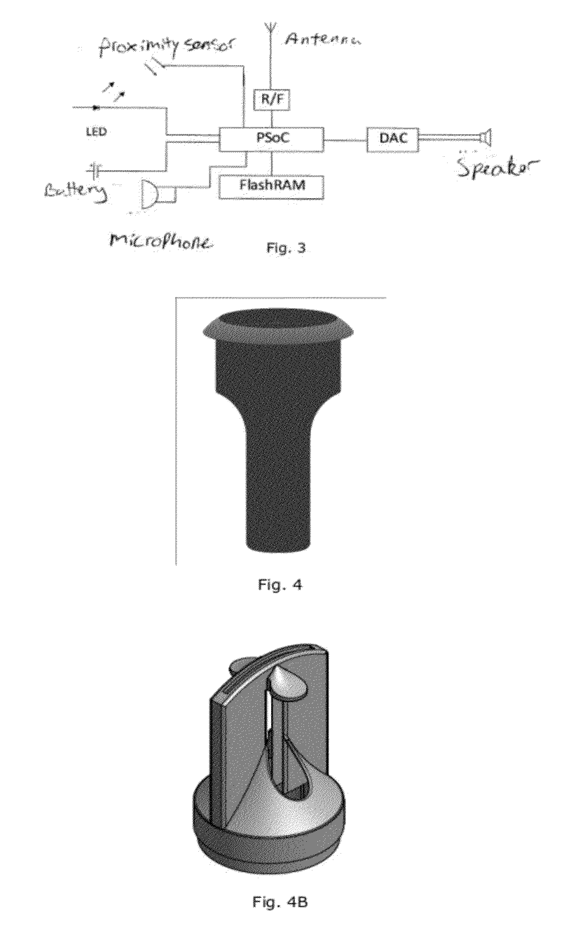

FIG. 3 is a schematic illustration of some components of an ornamental device according to the present invention.

The system is based on a PSoC principle, i.e. programmable system on a chip, where most of the functionality is performed by a single component. To achieve a good quality of sound an external Digital-to-analogue converter may be used, i.e. external to the processor. This may comprise an equalizer and filter module. Further, the electronic circuit comprises a memory device, e.g. a RAM device, and a transmitter/receiver circuit.

The PSoC system could be based on an ARM M3 or 8051 processor and have an analogue/digital frontend. The memory could be FlashRAM or other non-volatile memory. The sounds stored could be packaged lossless for best sound quality.

The power source could be a 3.8 V or two 1.5V battery, the life time of which could be one season, e.g. from November to January.

The microphone could be a surface mounted condenser microphone.

The Digital-to-Analogue converter could be a 1.4 W class D amplifier providing a high sound quality and a high efficiency, typically around 95%.

The speaker unit could be a 1″ fulltone unit having a relatively flat frequency response, with a maximum effect of 2 W.

The transceiver unit could advantageously operate in the 2.4 GHz range, and the antenna should be configured for the same frequency range, it may be a folded dipole antenna.

The operation of the ornamental device could be as follows: Unit the proximity device for detecting touch of the device, one short interaction, not actual touch: start music

Two short touches: stop music

Continuous touch: change volume, raise to maximum, then lower.

In an area with multiple ornamental devices a network may be established as described. It would be advantageous to limit the range of the network to a few meters, e.g. below 10 meters, as larger ranges would raise the risk of interference from devices of e.g. neighbors or other people not in the intended household.

The communication protocol is advantageously in the 2.4 GHz frequency band, and either ZigBee or Bluetooth-based. Other frequencies or frequency bands may be used. Generally the data rate and duty cycle should be adjusted to minimize energy consumption. During synchronization the data rate could be as high as 2.1 Mbit/sec, or higher depending on the communication protocol and signal quality.

The protocol used for the communication should include encryption to avoid unintended use. The base of the communication protocol could be 6LoWPAN based, which builds on the IPv6 protocol. The encryption could be proprietary.

When a mobile phone, e.g. iPhone, is connected to a base station, it could be possible to use the ornamental devices to play the music stored on the mobile phone via an application on the mobile phone.

The ornamental device may be provided without any song recorded, but the buyer may be allowed to download one song to the ornamental device. This will allow the buyer to choose his or her own song, as not all holiday songs are readily available. Also, it allow the buyer to record his or her own song and download that to the ornamental device. Further, the song may be overwritten so as to allow exchange of the original song, or just exchange of the song presently available on the ornamental device.

FIG. 4 is a perspective view of an embodiment of an inset device configured to carry all electronic components of the ornamental device, i.e. the circuits, power source, antenna etc.

FIG. 4B is a schematic illustration of a holder for device for holding two batteries in place inside the ornamental device. In this embodiment two AAA batteries are sufficient.

FIG. 5 is a schematic illustration of a part of an ornamental device. A number of apertures are formed in the device. The apertures are distributed around a point on the device whereby the pattern illustrated is formed. One or more of the apertures may be used for the purposes stated above, i.e. for inserting power cord for charging the power source, for establishing wired communication between an external device such as a computer, pc or mac, mobile phone, tablet computer or any other suitable device. Sound may also be emitted via the apertures. Some of the apertures may be closed at one end.

Generally the ornamental device is preloaded with only one music file, e.g. a song comprising voice and/or instrumental track. The name of the song is printed on the ornamental device or e.g. a ribbon attached to the ornamental device.

In order to activate playback of the music file the use touch the ornamental device briefly, this will initiate a transmission from the ornamental device being touched to other ornamental devices within communication range. The ornamental device comprises a light source, here an LED source, which flashes with a frequency of 1 to 2 Hertz. This indicates that the ornamental devices are activated; also it allows the user to visually confirm that the battery source is not depleted. Once the initialization of the set of ornamental devices has completed, the music stored in the ornamental device that was touched will begin to play from all ornamental devices that were part of the initiation process. The initiation process may include transferring the music file stored to the remaining ornamental devices.

The ornamental devices further comprise a volume function allowing the user to increase or decrease the volume outputted by the ornamental device or devices. When the user touches the ornamental device the volume is decreased. The volume is gradually decreased. By prolonged touch the volume reduces to zero. If the user continues to touch the ornamental device volume beings to increase until maximum, or until the user lets go of the ornamental device.

Touching only briefly the ornamental device while the stored music is being played back causes the play back to stop.

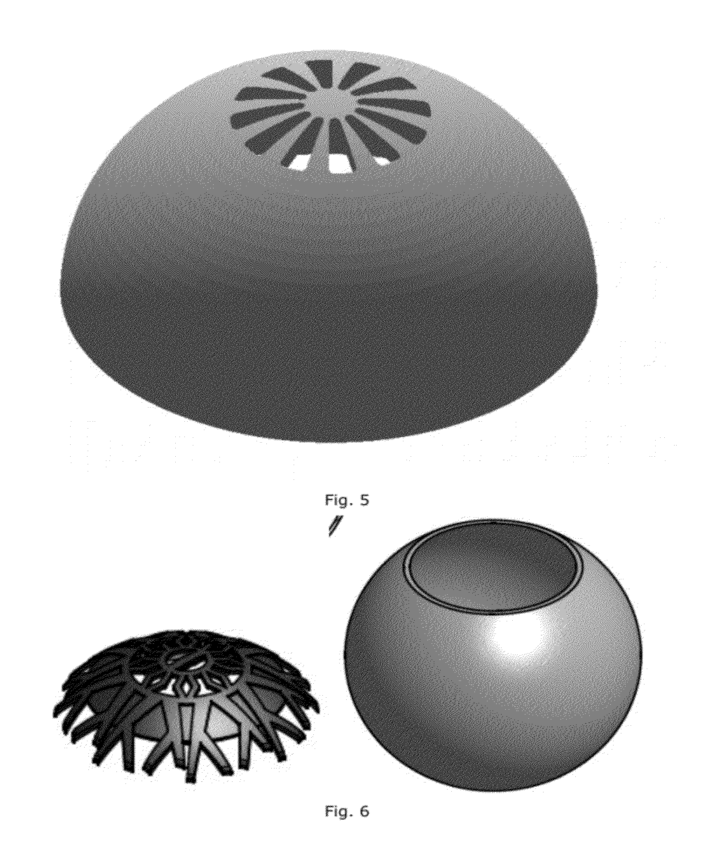

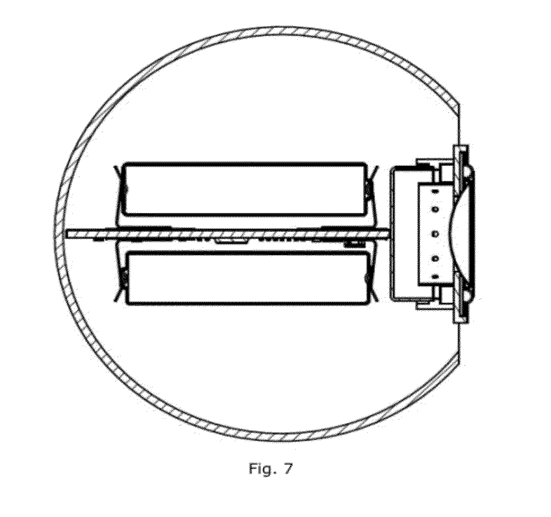

FIG. 6 is a schematic view of a set comprising a housing and a cap device for closing the opening in the housing. The opening in the housing is where the majority of the sound emitted escapes the ornamental device.

FIG. 7 is a schematic sectional view of an ornamental device where a set of batteries is held in the battery holding device. The battery holding device may be extracted from the housing when batteries are to be replaced. Further, the electronics, including a processor and memory, are mounted on the battery holding device.

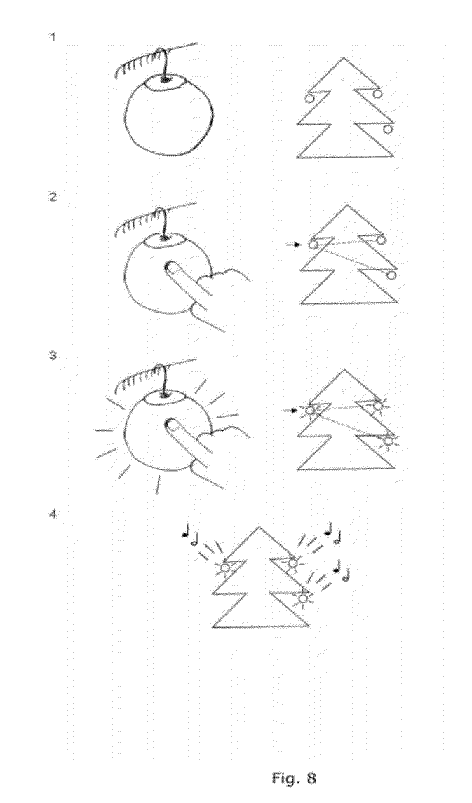

FIG. 8 is a set of schematic illustrations of steps of operating an ornamental device as described earlier.

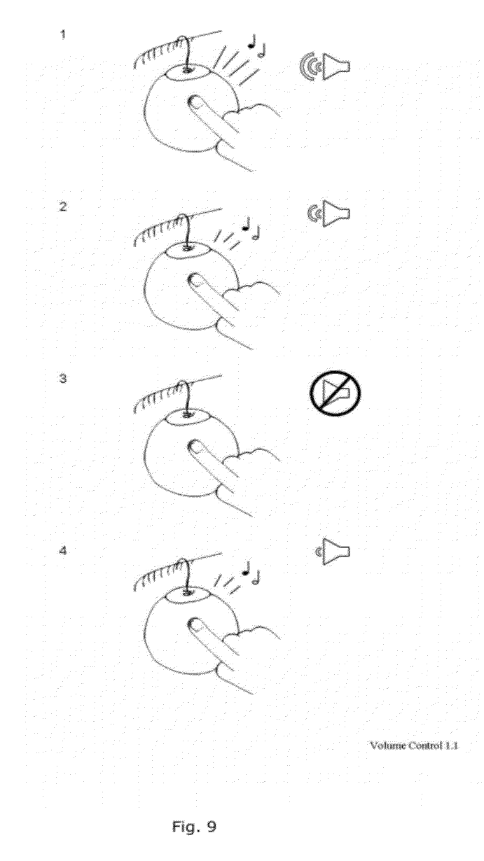

FIG. 9 is a set of schematic illustrations of steps of operating the sound level of an ornamental device.

Although the present invention has been described in connection with the specified embodiments, it should not be construed as being in any way limited to the presented examples. The scope of the present invention is set out by the accompanying claim set. In the context of the claims, the terms “comprising” or “comprises” do not exclude other possible elements or steps. Also, the mentioning of references such as “a” or “an” etc. should not be construed as excluding a plurality. The use of reference signs in the claims with respect to elements indicated in the figures shall also not be construed as limiting the scope of the invention. Furthermore, individual features mentioned in different claims, may possibly be advantageously combined, and the mentioning of these features in different claims does not exclude that a combination of features is not possible and advantageous.

The present invention may be characterized by the following points:
1. An ornamental device comprising:
   a housing including an opening for emitting sound,
   a sound emitting device mounted in the housing,
   a memory device in the housing for storing sound to be emitted,
   a processor configured to access the memory device and configured to operate the sound emitting device so as to emit desired sounds, and
   a transceiver for transmitting the sound stored in the memory device to a neighboring ornamental device.
2. The ornamental device according to point 1, wherein the transceiver is configured to receive sound information from a neighboring ornamental device.
3. The ornamental device according to point 1 or 2, further comprising a proximity sensor for establishing touch control of the ornamental device.
4. The ornamental device according to point 3, wherein the proximity sensor is a capacitive device.
5. The ornamental device according to any one of the points 1-4, further comprising a microphone, wherein the processor is configured to adapt the volume of emitted sound via the sound emitting device based on information from the microphone.
6. The ornamental device according to point 5, wherein the processor is configured to detect back-ground sounds and perform the adaptation the volume of emitted sound via the sound emitting device based on the level of back-ground sound.
7. The ornamental device according to any one of the points 1-6, further comprising a lighting device.
8. The ornamental device according to point 7, wherein the lighting device is configured to provide light of a number of different colors and/or intensities.

What is claimed is:

1. An ornamental device comprising:
a housing including an opening for emitting sound,
a sound emitting device mounted in the housing,
a memory device in the housing for storing sound to be emitted,
a processor arranged in the housing, the processor connected to the memory device and the sound emitting device, the processor comprising a software program for controlling playback of desired sounds stored in the memory, and
a transceiver for transmitting the sound stored in the memory device to a neighboring ornamental device.

2. The ornamental device according to claim 1, wherein the transceiver is configured for detecting presence of a second ornamental device within a range below a threshold.

3. The ornamental device according to claim 1, wherein the transceiver is configured or arranged to receive sound information from a neighboring ornamental device.

4. The ornamental device according to claim 1, further comprising a proximity sensor for establishing touch control of the ornamental device.

5. The ornamental device according to claim 4, wherein the proximity sensor is a capacitive device.

6. The ornamental device according to claim 1, further comprising a microphone, wherein the processor adapts the volume of emitted sound via the sound emitting device based on information from the microphone.

7. The ornamental device according to claim 6, wherein the processor detects level of back-ground sounds via the microphone and adapts the volume of emitted sound via the sound emitting device based on the level of back-ground sound.

8. The ornamental device according to claim 1, further comprising a lighting device or light emitting device.

9. The ornamental device according to claim 8, wherein the lighting device provides light of a number of different colors and/or intensities controlled by the processor.

10. A method of controlling an ornamental device comprising
a housing including an opening for emitting sound,
a sound emitting device mounted in the housing, a memory device in the housing for storing sound to be emitted,
a processor arranged in the housing, the processor connected to the memory device and the sound emitting device, the processor comprising a software program for controlling playback of desired sounds stored in the memory, and
a transceiver for transmitting the sound stored in the memory device to a neighboring ornamental device,
the method comprising:
operating the processor to cause stored sound from the memory to be emitted via the sound emitting device.

11. The method according to claim 10, further comprising:
detecting presence of a second ornamental device, and
transferring stored sound from the ornamental device to the second ornamental device, wherein the stored sound from the ornamental device is played back on the second ornamental device if the ornamental device is within a first range from the second ornamental device.

12. The method according to claim 11, wherein the first range is 1-10 meters.

13. The method according to claim 10, wherein the ornamental device comprises a proximity sensor, the method comprising detecting touch via the proximity sensor and adapting sound emission level based on input from the proximity sensor.
